(19) United States
(12) Patent Application Publication
(10) Pub. No.: US 2013/0252819 A1
(43) Pub. Date: Sep. 26, 2013

(54) CRYO-MAGNETIC MOTOR

(71) Applicant: Yuriy Zakuskin, Orekhov (UA)

(72) Inventor: Yuriy Zakuskin, Orekhov (UA)

(21) Appl. No.: 13/429,497

(22) Filed: Mar. 26, 2012

(51) Int. Cl. H02K 55/00; H01L 39/02

(52) U.S. Cl. 505/166; 310/46

(57) ABSTRACT

A cryo-magnetic motor is described. The motor includes a magnetic rotor having a first portion and a second portion. The motor can also include a stator assembly having an insulated casing, a liquid chamber, and a superconducting plate.

Embodiments relate generally to electric motors, and, more particularly, to an electric motor having a stator with a superconductor element.

One embodiment includes a motor having a magnetic rotor having a first portion and a second portion and a stator assembly. The stator assembly can include an insulated casing, a liquid chamber, and a plate made of a superconducting material.

One embodiment includes a motor having a magnetic rotor having a first portion with a first polarity and a second portion with a second polarity different from the first polarity, a stator assembly. The stator assembly includes an insulated casing adapted to insulate liquid helium, a liquid chamber configured to store liquid helium and being filled with liquid helium, and a superconducting plate formed from lead.

Another embodiment includes an electric motor having a magnetic rotor having a first portion with a first polarity and a second portion with a second polarity different from the first polarity, and a stator assembly. The stator assembly can include an insulated casing adapted to insulate liquid nitrogen, a liquid chamber configured to store liquid nitrogen and being filled with liquid nitrogen, and a superconducting plate formed from a ceramic superconductor material.

### BRIEF DESCRIPTION OF THE DRAWINGS

FIG. 1 is a cross sectional diagram of an exemplary cryo-magnetic motor in accordance with at least one embodiment.

### DETAILED DESCRIPTION

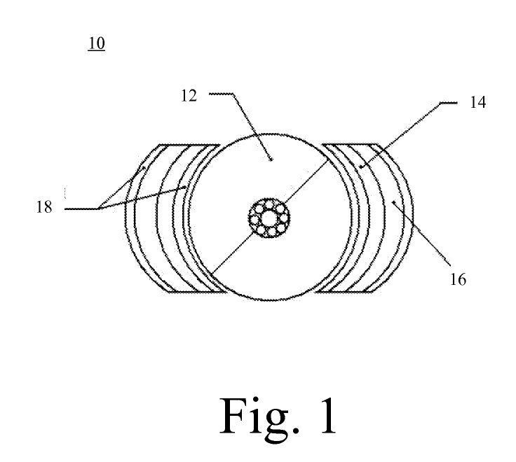

FIG. 1 shows a diagram of an exemplary cryo-magnetic motor 10. The motor 10 includes a magnetic rotor 12, a superconducting plate element 14, a liquid chamber 16 and an insulated container 18.

The magnetic rotor 12 can have two portions each with a different magnetic polarity.

The superconductor element 14 can include various superconductor materials such as, for example, copper-oxide superconductors (e.g., HgBa2Ca2Cu3Ox, Bi2Sr2Ca2Cu3O10(BSCCO), and YBa2Cu3O7 (YBCO)); iron-based superconductors SmFeAs(O,F), CeFeAs(O,F), LaFeAs(O,F); metallic low-temperature superconductors (NbTi, Nb, and Pb).

The liquid chamber 16 can be used to hold liquid gases such as liquefied nitrogen or helium, and can include a pressure relief valve. The insulated container 18 can be a Dewar flask, or the like. It will be appreciated that the insulated container 18 can be formed having a shape and size to fit and operate with the motor. Also, the motor can include an outer enclosure so that gases that are boiled off can be captured for reuse.

In operation, the liquid chamber(s) 16 are filled with a liquefied gas with a boiling point sufficiently low enough to enable the superconductor plate material to reach critical temperature and exhibit the Meissner effect.

Once the superconducting plates have reached the critical temperature for the respective material, the superconducting plates can reflect or exclude magnetic flux energy.

It will be appreciated that other standard components can be used, but have been omitted from the drawings for purposes of clearly conveying the various embodiments. Standard components can include, but are not limited to, control circuits and the like.

It is, therefore, apparent that there is provided, in accordance with the various embodiments disclosed herein, a cryo-magnetic motor.

While the invention has been described in conjunction with a number of embodiments, it is evident that many alternatives, modifications and variations would be or are apparent to those of ordinary skill in the applicable arts. Accordingly, Applicant intends to embrace all such alternatives, modifications, equivalents and variations that are within the spirit and scope of the invention.

What is claimed is:

1. A motor comprising:
a magnetic rotor having a first portion and a second portion;
a stator assembly including:
an insulated casing,
a liquid chamber, and
a superconducting plate.

2. The motor of claim 1, wherein the insulated casing is a Dewar flask.

3. The motor of claim 1, wherein the liquid chamber is configured to contain a liquified gas.

4. The motor of claim 1, wherein the superconducting plate is formed from lead.

5. The motor of claim 4, wherein the liquid chamber is filled with liquid helium.

6. The motor of claim 1, wherein the superconducting plate is formed from a ceramic superconductor.

7. The motor of claim 1, wherein the liquid chamber is filled with liquid nitrogen.

8. The motor of claim 5, wherein the insulated casing is configured to keep liquid helium insulated.

9. The motor of claim 7, wherein the insulted casing is configured to keep liquid nitrogen insulated.

10. The motor of claim 1, further comprising a pressure relief valve disposed on the liquid chamber and configured to relive pressure from the liquid chamber.

11. A motor comprising:
a magnetic rotor having a first portion with a first polarity and a second portion with a second polarity different from the first polarity;
a stator assembly including:
an insulated casing adapted to insulate liquid helium,
a liquid chamber configured to store liquid helium and being filled with liquid helium, and
a superconducting plate formed from lead.

12. A motor comprising:
a magnetic rotor having a first portion with a first polarity and a second portion with a second polarity different from the first polarity;
a stator assembly including:
an insulated casing adapted to insulate liquid nitrogen,
a liquid chamber configured to store liquid nitrogen and being filled with liquid nitrogen, and
a superconducting plate formed from a ceramic superconductor material.
